(19) United States
(12) Patent Application Publication
(10) Pub. No.: US 2025/0385574 A1
(43) Pub. Date: Dec. 18, 2025

(54) ELECTRONIC DEVICE

(71) Applicant: HYUNDAI MOBIS CO., LTD., Seoul (KR)

(72) Inventor: Min Gu KIM, Yongin-si (KR)

(73) Assignee: HYUNDAI MOBIS CO., LTD., Seoul (KR)

(21) Appl. No.: 19/001,160

(22) Filed: Dec. 24, 2024

(30) Foreign Application Priority Data
Jun. 18, 2024 (KR) 10-2024-0078934

(51) Int. Cl. H02K 9/22; H02K 11/33; H05K 7/20

(52) U.S. Cl. CPC H02K 9/227; H02K 11/33; H05K 7/2039; H02K 2211/03

(57) ABSTRACT

Provided is an electronic device, which includes a motor housing portion wherein a motor is positioned, a cover portion coupled with the motor housing portion and configured to include a cover hole portion, a circuit board portion configured to include an electronic element portion that controls the motor and generates heat and positioned between the motor housing portion and the cover portion, a housing heat sink portion positioned between the circuit board portion and the motor housing portion and configured to make contact with one side of the circuit board portion to dissipate heat, and a cover heat sink portion positioned to be inserted into the cover hole portion between the circuit board portion and the cover portion and configured to make contact with the opposite side of the circuit board portion to dissipate heat.

### CROSS-REFERENCE TO RELATED APPLICATION

This application claims priority from and the benefit of Korean Patent Application No. 10-2024-0078934, filed on Jun. 18, 2024, which is hereby incorporated by reference for all purposes as if set forth herein.

### BACKGROUND

### Field

Exemplary embodiments according to the present disclosure relate to an electronic device, and more particularly, to an electronic device having a heat sink structure applied to both sides of a circuit board inside the electronic device.

### Discussion of the Background

As the amount of power consumed by electronic devices increases, heat generated by heating elements in the electronic devices is also increasing. Since heat generation shortens the lifespan of electronic devices, it is desirable to suppress heat generation in the heating elements and maximize heat dissipation performance.

To maximize the heat dissipation performance, it is essential to increase the heat dissipation area. However, increasing the heat dissipation area also increases the volume of the electronic device. To maximize an internal space of a vehicle, it is desirable to minimize the volume of the electronic device. Therefore, a proper balance is needed among suppressing heat generation in the heating elements of the electronic device, maximizing the heat dissipation performance, and miniaturizing the electronic device.

The related art of the present disclosure is disclosed in Korean Patent No. 10-2147658 (registered on Aug. 19, 2020 and entitled “A COOLING APPARATUS FOR ELECTRONIC ELEMENTS”).

### SUMMARY

Various embodiments of the present disclosure are directed to providing an electronic device capable of improving heat dissipation performance in a minimal volume.

In addition, the embodiments of the present disclosure are directed to providing an electronic device having improved durability.

Furthermore, the embodiments of the present disclosure are directed to providing an electronic device capable of operating through a redundancy structure even in a failed state of an electronic element.

An electronic device according to the present disclosure includes a motor housing portion wherein a motor is positioned, a cover portion coupled with the motor housing portion and configured to include a cover hole portion, a circuit board portion configured to include an electronic element portion that controls the motor and generates heat and positioned between the motor housing portion and the cover portion, a housing heat sink portion positioned between the circuit board portion and the motor housing portion and configured to make contact with one side of the circuit board portion to dissipate heat, and a cover heat sink portion positioned to be inserted into the cover hole portion between the circuit board portion and the cover portion and configured to make contact with the opposite side of the circuit board portion to dissipate heat.

The cover heat sink portion may include a cover heat sink body configured to make contact with the electronic element portion and a cover heat sink fin configured to protrude from the cover heat sink body.

The cover heat sink portion may further include a cover heat sink groove recessed in the cover heat sink body to surround the cover heat sink fin. The cover portion may include a cover body and a cover body protrusion configured to protrude from the cover body and be inserted into the cover heat sink groove to block the cover hole portion.

The cover heat sink portion may be secured to the motor housing portion and apply pressure to the circuit board portion toward the motor housing portion.

The cover heat sink portion may include a cover heat sink hole provided with a through-hole in the cover heat sink body and include a cover heat sink coupling member configured to pass through the cover heat sink hole and coupled with the motor housing portion.

The cover heat sink portion may be insert-molded with the cover portion, secured to the cover portion, and apply pressure to the circuit board portion toward the motor housing portion.

The cover heat sink portion may make contact with the electronic element portion positioned on the opposite side of the circuit board portion. The housing heat sink portion may be positioned to correspond to a position of the electronic element portion on one side of the circuit board portion.

The electronic element portion may include a first electronic element portion and a second electronic element portion.

The cover heat sink portion may include a first cover heat sink body configured to make contact with the first electronic element portion and a second cover heat sink body configured to make contact with the second electronic element portion.

The housing heat sink portion may include a first housing heat sink body positioned to correspond to a position of the first electronic element portion and a second housing heat sink body positioned to correspond to a position of the second electronic element portion.

The cover heat sink portion may include a sealant applied between the cover heat sink groove and the cover body protrusion to block the cover hole portion.

The cover heat sink portion may include a sealing positioned between the cover heat sink groove and the cover body protrusion to block the cover hole portion.

The cover heat sink portion may include a cover heat sink plate configured to extend from the cover heat sink body and inserted into the cover portion.

Based on a situation where the first electronic element portion is non-operational, the second electronic element portion may perform the function of the first electronic element portion.

The second electronic element portion may perform a function that assists the first electronic element portion.

The cover hole portion may include a first cover hole into which the first cover heat sink body is inserted and a second cover hole into which the second cover heat sink body is inserted.

The electronic device according to the present disclosure enables the improvement of heat dissipation performance in a minimal volume.

In addition, the electronic device according to the present disclosure enables the improvement of durability.

Furthermore, the electronic device according to the present disclosure is capable of operating through the redundancy structure even in a failed state.

### BRIEF DESCRIPTION OF THE DRAWINGS

FIG. 1 is a perspective view schematically showing an electronic device according to an embodiment of the present disclosure.

FIG. 2 is an exploded perspective view of the electronic device according to the embodiment of the present disclosure, viewed from a first perspective.

FIG. 3 is an exploded perspective view of the electronic device according to the embodiment of the present disclosure, viewed from a second perspective.

FIG. 4 is a cross-sectional view of a first embodiment of a cover heat sink portion of the electronic device according to the present disclosure.

FIG. 5 is a perspective view of the first embodiment of the cover heat sink portion of the electronic device according to the present disclosure.

FIG. 6 is a cross-sectional view of a second embodiment of the cover heat sink portion of the electronic device according to the present disclosure.

FIG. 7 is a perspective view of the second embodiment of the cover heat sink portion of the electronic device according to the present disclosure.

FIG. 8 is a perspective view of an electronic device according to another embodiment of the present disclosure.

FIG. 9 is an exploded perspective view of the electronic device according to another embodiment of the present disclosure.

### DETAILED DESCRIPTION OF THE ILLUSTRATED EMBODIMENTS

Embodiments of an electronic device according to the present disclosure will be described hereinafter with reference to the accompanying drawings. In this process, the thickness of lines and the size of elements illustrated in the drawing may be exaggerated for clarity and convenience of description. In addition, the terms used below are defined in consideration of the functions thereof in the present disclosure and may vary depending on the intention of a user or an operator or common practice. Therefore, these terms should be contextually defined in light of the present specification.

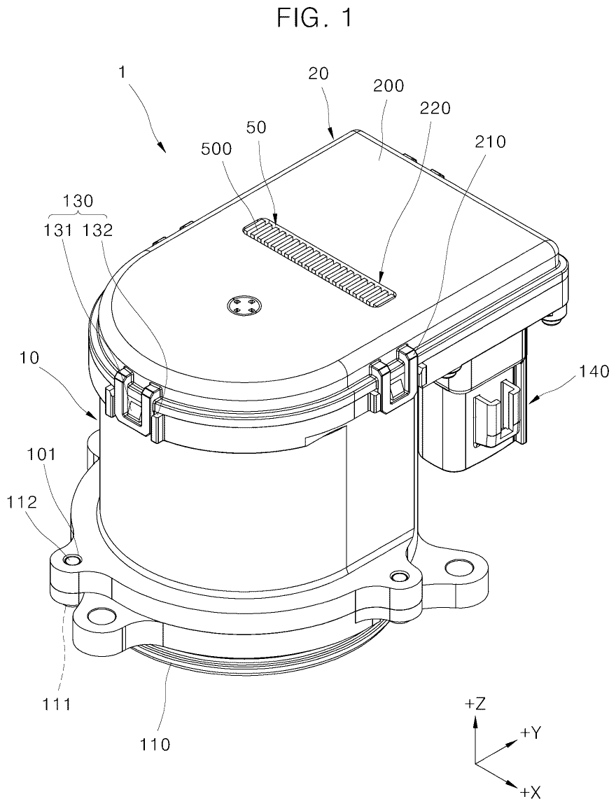

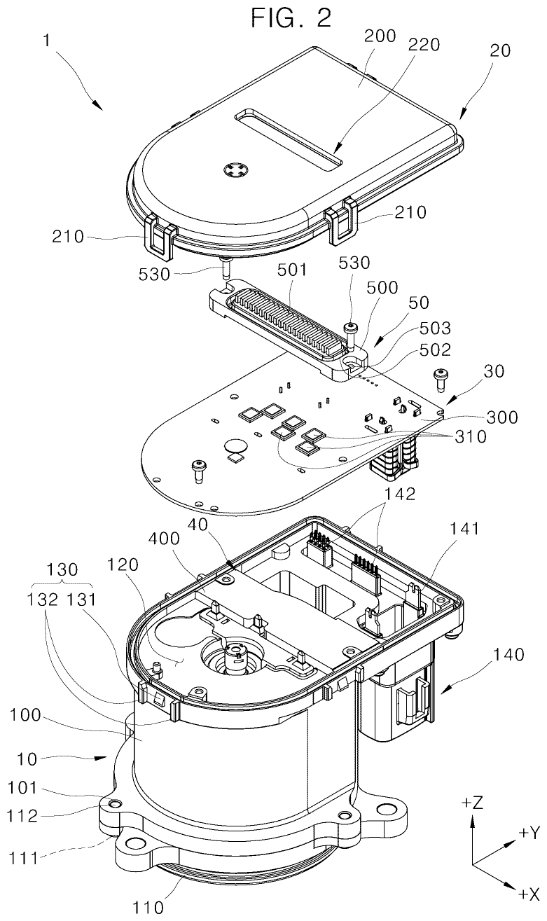

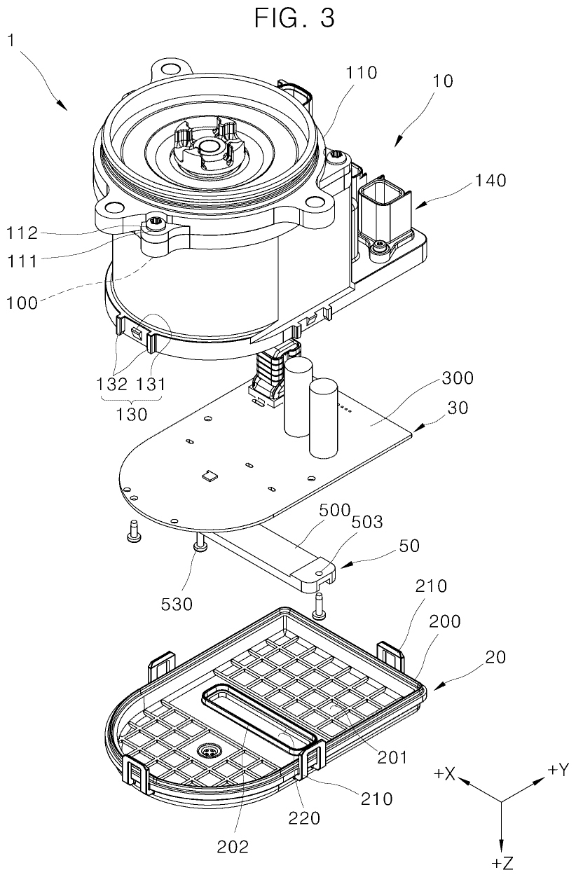

FIG. 1 is a perspective view schematically showing an electronic device according to an embodiment of the present disclosure. FIG. 2 is an exploded perspective view of the electronic device according to the embodiment of the present disclosure, viewed from a first perspective. FIG. 3 is an exploded perspective view of the electronic device according to the embodiment of the present disclosure, viewed from a second perspective.

Referring to FIGS. 1 to 3, an electronic device 1 may be used in a vehicle and adjust a steering angle of the vehicle. The electronic device 1 may receive a user's steering wheel angle signal and drive a motor. The steering angle of the vehicle may be adjusted by driving the motor of the electronic device 1.

The electronic device 1 may adjust a front wheel steering angle or a rear wheel steering angle of the vehicle. According to an embodiment, the electronic device 1 may be configured to be used for rear wheel steering (RWS). The electronic device 1 may receive the user's steering wheel angle signal and adjust the rear wheel steering angle of the vehicle. The electronic device 1 may include a motor and adjust the rear-wheel steering angle of the vehicle by driving the motor in response to the user's steering wheel angle signal.

A schematic configuration of the electronic device 1 will be described below.

The electronic device 1 may include a motor housing portion 10, a cover portion 20, a circuit board portion 30, a housing heat sink portion 40, and a cover heat sink portion 50.

A motor may be positioned inside the motor housing portion 10. A circuit board portion 30 may be positioned between the motor housing portion 10 and the cover portion 20. The housing heat sink portion 40 may be positioned between the circuit board portion 30 and the motor housing portion 10, and the cover heat sink portion 50 may be positioned between the circuit board portion and the cover portion 20.

The circuit board portion 30 may receive the user's steering wheel angle signal and adjust the rear-wheel steering angle of the vehicle by driving the motor in response to the user's steering wheel angle signal. The circuit board portion may include an electronic element portion 310 that controls the motor. The electronic element portion 310 generates heat during operation, so it is necessary to dissipate the heat from the electronic element portion 310. The heat-generating electronic element portion 310 may be positioned on one of the two sides of the circuit board portion 30, specifically on the side facing the cover portion 20. The embodiment of the present invention is not limited to the position of the electronic element portion 310 on one side of the circuit board portion 30 facing the cover portion 20, and the present disclosure includes an embodiment in which the electronic element portion 310 is positioned on the side facing the motor housing portion 10.

The housing heat sink portion 40 and the cover heat sink portion 50 may dissipate heat generated from the circuit board portion 30. According to an embodiment, the housing heat sink portion 40 and the cover heat sink portion 50 may dissipate heat generated from the electronic element portion 310.

According to an embodiment, the housing heat sink portion 40 may make contact with the circuit board portion 30, which is positioned at a location corresponding to where the electronic element portion 310 is positioned, and dissipate the heat from the electronic element portion 310. The cover heat sink portion 50 may make contact with the electronic element portion 310 and dissipate the heat from the electronic element portion 310.

According to another embodiment, the housing heat sink portion 40 may make contact with the electronic element portion 310 and dissipate the heat from the electronic element portion 310. The cover heat sink portion 50 may make contact with the circuit board portion 30, which is positioned at a location corresponding to where the electronic element portion 310 is positioned, and dissipate the heat from the electronic element portion 310.

The housing heat sink portion 40 may be positioned on the motor housing portion 10, or the housing heat sink portion 40 may be integrally formed with the motor housing portion 10.

The cover heat sink portion 50 may be positioned on the cover portion and make contact with the cover portion 20.

According to an embodiment, the cover heat sink portion 50 may be coupled with the motor housing portion 10 and secured to the motor housing portion 10. According to another embodiment, the cover heat sink portion 50 may be insert-molded and inserted into the cover portion 20.

The cover heat sink portion 50 may be inserted into a hole formed in the cover portion 20 and exposed to the outside of the cover portion 20. As the cover heat sink portion 50 is exposed to the outside of the cover portion 20, the heat dissipation performance of the electronic device 1 may be improved by the cover heat sink portion 50.

A detailed configuration of the electronic device 1 will be described below.

The motor housing portion 10 may include a motor housing body 100, a motor housing cap 110, a motor housing seating portion 120, a motor housing coupling portion 130, and a motor housing plug 140.

The motor housing body 100 may form an internal space. A motor may be positioned inside the motor housing body 100. The motor positioned inside the motor housing body 100 may be driven to adjust the steering angle of the vehicle. According to an embodiment, the motor may adjust the rear-wheel steering angle of the vehicle. The motor may be controlled and driven by the circuit board portion 30.

The motor housing cap 110 may be positioned on one side (e.g., in the −Z-axis direction) of the motor housing body 100, and the cover portion 20 may be positioned on the other side (e.g., in the +Z-axis direction).

A motor housing body hole 101 may be positioned on the motor housing body 100. The motor housing body hole 101 may be positioned to align with a motor housing cap hole 111 of the motor housing cap 110 so that they may be coupled by a motor housing coupling member 112.

The motor housing cap 110 may be positioned on one side of the motor housing body 100 (e.g., in the −Z-axis direction). The motor housing cap hole 111 may be positioned on the motor housing cap 110, and the motor housing cap hole 111 may be positioned to align with the motor housing body hole 101.

The motor housing coupling member 112 may pass through the motor housing body hole 101 and the motor housing cap hole 111 to couple the motor housing body 100 with the motor housing cap 110. According to an embodiment, the motor housing coupling member 112 may be provided with a bolt and nut, or alternatively, with a rivet.

The motor housing seating portion 120 may be formed in the motor housing body 100.

According to an embodiment, the motor housing seating portion 120 may be provided with a space recessed from the other side (e.g., in the +Z-axis direction) toward one side (e.g., in the −Z-axis direction) of the motor housing body 100.

According to another embodiment, the motor housing seating portion 120 may be provided with a surface formed on the other side (e.g., in the +Z-axis direction) of the motor housing body 100.

According to yet another embodiment, the motor housing seating portion 120 may be provided with a surface formed to protrude from the other side of the motor housing body 100.

The circuit board portion 30 may be positioned on the motor housing seating portion 120. The circuit board portion 30 may be positioned on the motor housing seating portion 120 and have heat dissipated through the housing heat sink portion 40. The housing heat sink portion 40 may be integrally formed with the motor housing portion 10, or may be coupled with the motor housing portion 10.

The motor housing coupling portion 130 may be provided on the motor housing body 100 and couple the motor housing portion 10 with the cover portion 20. The motor housing coupling portion 130 may be coupled with a cover body coupling portion 210 of the cover portion 20. As the motor housing coupling portion 130 and the cover body coupling portion 210 are coupled, the other side of the motor housing portion 10 (e.g., in the +Z-axis direction) may be sealed by the cover portion 20. Accordingly, foreign substances may be prevented from entering the interior of the electronic device 1.

The motor housing coupling portion 130 may include a motor housing coupling protrusion 131 and a motor housing coupling guide 132.

The motor housing coupling protrusion 131 may be coupled with the cover body coupling portion 210 and prevent the cover body coupling portion 210 from detaching from the motor housing body 100. The motor housing coupling protrusion 131 may be configured to protrude outward from the motor housing body 100.

The motor housing coupling guide 132 may guide the movement of the cover body coupling portion 210. The motor housing coupling guide 132 may be positioned on both sides of the motor housing coupling protrusion 131. As the cover body coupling portion 210 makes contact with the motor housing coupling guide 132, the movement direction of the cover body coupling portion 210 may be restricted. Accordingly, the cover body coupling portion 210 may be easily coupled with the motor housing coupling protrusion 131.

The motor housing plug 140 may be positioned on the motor housing body 100 and coupled with a connector. The motor housing plug 140 may receive power from a configuration external to the electronic device 1 or receive signals used to drive the motor.

The motor housing plug 140 may be connected to a power transfer portion 141 and a signal transfer portion 142. The power transfer portion 141 may transfer power required for driving the motor. The signal transfer portion 142 may transfer a signal required for driving the motor. The power transfer portion 141 and the signal transfer portion 142 may be connected to the motor and/or the circuit board portion 30.

The cover portion 20 may include a cover body 200, a cover body recess 201, a cover body protrusion 202, a cover body coupling portion 210, and a cover hole portion 220.

The cover body 200 may be coupled to the motor housing body 100.

The cover body 200 may be coupled with the motor housing body 100 to form a space enclosed by the cover body 200 and the motor housing body 100. The circuit board portion 30 may be positioned in a space enclosed by the cover body 200 and the motor housing body 100.

The cover body 200 may include the cover body recess 201, which is recessed from the lower side (e.g., in the −Z-axis direction) to the upper side (e.g., in the +Z-axis direction). As the cover body 200 includes the cover body recess 201, the volume of the space enclosed by the cover body 200 and the motor housing body 100 may increase. Accordingly, the circuit board portion 30 may be positioned in the cover body recess 201.

The cover body protrusion 202 may be positioned on the lower side (e.g., in the −Z-axis direction) of the cover body 200. The cover body protrusion 202 may be formed to protrude toward the lower side of the cover body 200.

The cover body protrusion 202 may or may not be formed on the cover body 200, depending on an embodiment of the cover heat sink portion 50. According to an embodiment, the cover body protrusion 202 may be inserted into a cover heat sink groove 502 when the cover heat sink groove 502 is formed in the cover heat sink portion 50. According to another embodiment, the cover body protrusion 202 may not be formed on the cover body 200 when the cover heat sink groove 502 is not formed in the cover heat sink portion 50.

The cover body coupling portion 210 may be positioned on the cover body 200. According to an embodiment, the cover body coupling portion 210 may be positioned on the outer portion of the cover body 200.

The cover body coupling portion 210 may be coupled with the motor housing portion 10. According to an embodiment, the cover body coupling portion 210 may be coupled with the motor housing coupling portion 130. The motor housing coupling guide 132 may guide the movement of the cover body coupling portion 210. The cover body coupling portion 210 may be coupled with the motor housing coupling protrusion 131 to prevent the cover portion 20 from detaching from the motor housing portion 10.

The cover hole portion 220 may be positioned in the cover body 200. The cover hole portion 220 may be provided with a through-hole in the cover body 200. The shape of the cover hole portion 220 may be substantially square. According to an embodiment, the shape of the cover hole portion 220 may be substantially rectangular. The shape of the cover hole portion 220 may align with the shape of the cover heat sink portion 50 that is inserted into the cover hole portion 220. The cover heat sink portion 50 may be inserted into the cover hole portion 220. As the cover heat sink portion 50 is inserted into the cover hole portion 220, the cover heat sink portion 50 may be exposed to the outside of the cover portion 20.

The circuit board portion 30 may be positioned between the motor housing portion 10 and the cover portion 20. According to an embodiment, the circuit board portion 30 may be positioned between the motor housing body 100 and the cover body 200. The circuit board portion 30 may include a circuit board body 300 and the electronic element portion 310.

The circuit board body 300 may be provided with a printed circuit board (PCB). The circuit board body 300 may be connected to the power transfer portion 141 and/or the signal transfer portion 142 and receive power or signals. The circuit board body 300 may control the drive of the motor through the received power or signal.

The electronic element portion 310 may be positioned on the circuit board body 300. The electronic element portion 310 may process the received signal to generate the signal required for driving the motor. The electronic element portion 310 may generate heat in the process of processing and generating signals.

The electronic element portion 310 may be positioned on the other side (e.g., in the +Z-axis direction) of the circuit board body 300. The embodiment of the present disclosure is not limited to the electronic element portion 310 being positioned on the other side (e.g., in the +Z-axis direction) of the circuit board body 300, and the present disclosure may include an embodiment in which the electronic element portion 310 is positioned on one side (e.g., in the −Z-axis direction) of the circuit board body 300.

The circuit board body 300 may make contact with the housing heat sink portion 40 and/or the cover heat sink portion 50. The housing heat sink portion may be positioned on one side (e.g., in the −Z-axis direction) of the circuit board body 300, and the cover heat sink portion 50 may be positioned on the other side (e.g., in the +Z-axis direction).

As the circuit board body 300 makes contact with the housing heat sink portion 40 and/or the cover heat sink portion 50, the heat generated from the electronic element portion 310 may be transferred to the housing heat sink portion 40 and/or the cover heat sink portion 50 for dissipation. Accordingly, the heat dissipation area of the electronic element portion 310 may increase.

As the heat dissipation area of the electronic element portion 310 increases, the heat dissipation performance may be improved, the temperature of the electronic element portion 310 may be kept low, and the durability of the electronic element portion 310 may be improved.

The housing heat sink portion 40 may include a housing heat sink body 400. The housing heat sink body 400 may include a material with good thermal conductivity. According to an embodiment, the housing heat sink body 400 may include metal.

The housing heat sink body 400 may be integrally formed with the motor housing body 100, or may be positioned on the motor housing body 100. The housing heat sink body 400 may be positioned at a location corresponding to where the electronic element portion 310 is positioned on the circuit board body 300. Accordingly, the heat from the electronic element portion 310 may be efficiently dissipated.

The cover heat sink portion 50 may include a cover heat sink body 500 and a cover heat sink fin 501. The cover heat sink portion 50 may further include a cover heat sink groove 502, a cover heat sink hole 503, and a cover heat sink plate 504.

The cover heat sink body 500 may include a material with good thermal conductivity. According to an embodiment, the cover heat sink body 500 may include metal. The cover heat sink body 500 may be configured to have a substantially hexahedral shape.

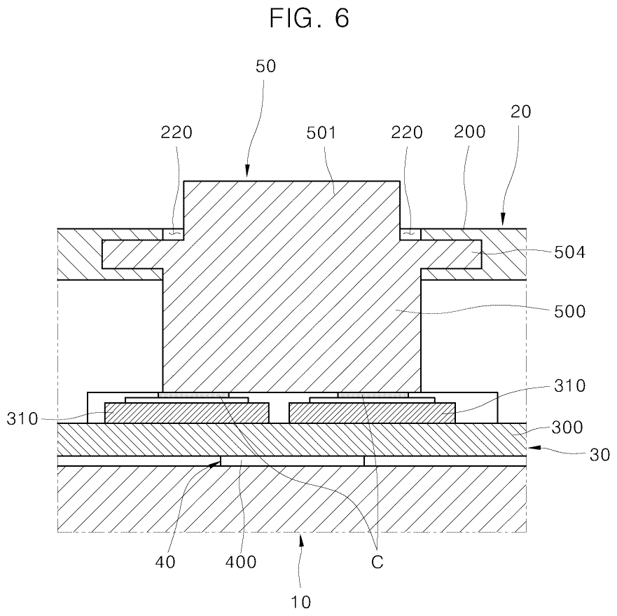

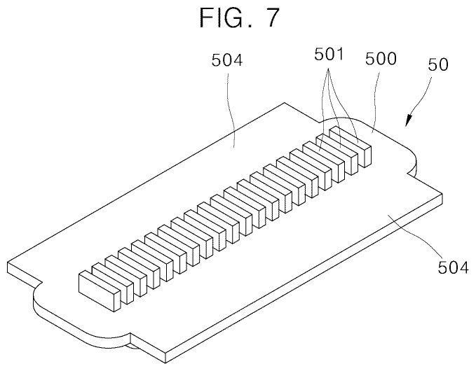

The cover heat sink body 500 may be positioned on the cover portion (see FIGS. 3 to 5) or may be integrally formed with the cover portion 20 (see FIGS. 6 and 7). An embodiment in which the cover heat sink body 500 is integrally formed with the cover portion 20 will be described below with reference to FIGS. 6 and 7.

On an upper side of the cover heat sink body 500 (e.g., in the +Z-axis direction), the cover heat sink fin 501 may be positioned. The cover heat sink fin 501 may extend upward from the cover heat sink body 500. A plurality of cover heat sink fins 501 may be provided. The plurality of cover heat sink fins 501 may be positioned in parallel to enable heat exchange with air. As the plurality of cover heat sink fins 501 is provided, the heat dissipation area may increase and the heat dissipation performance may be improved.

The cover heat sink groove 502 may be positioned with a recessed groove in the cover heat sink body 500. The cover heat sink groove 502 may be positioned to surround the cover heat sink fin 501. The planar shape of the cover heat sink groove 502 may be substantially square. The cover heat sink groove 502 may be positioned to make contact with the cover body protrusion 202 of the cover portion 20. The cover body protrusion 202 may be inserted into the cover heat sink groove 502 to block the cover hole portion 220. The cover body protrusion 202 may be inserted into the cover heat sink groove 502 to block the communication between one side and the other side of the cover hole portion 220.

As the cover heat sink body 500 is exposed to the outside of the cover portion 20, the heat dissipation performance of the electronic device 1 may be improved while maintaining the area of the cover heat sink body 500. The cover heat sink fin 501 may be exposed to the outside of the cover portion 20 through the cover hole portion 220.

The cover heat sink hole 503 may be provided with a through-hole in the cover heat sink body 500. The cover heat sink hole 503 may be positioned at both ends of the cover heat sink body 500 in the longitudinal direction. A cover heat sink coupling member 530 may be inserted into and secured to the motor housing body 100 through the cover heat sink hole 503. The cover heat sink coupling member 530 may apply pressure to the cover heat sink body 500 toward the motor housing body 100. Accordingly, the cover heat sink body 500 may be in close contact with the electronic element portion 310, and heat transfer from the electronic element portion 310 to the cover heat sink body 500 may be facilitated.

The cover heat sink coupling member 530 may be provided with a bolt. The cover heat sink coupling member 530 is not limited to a bolt and may include various coupling members such as a rivet.

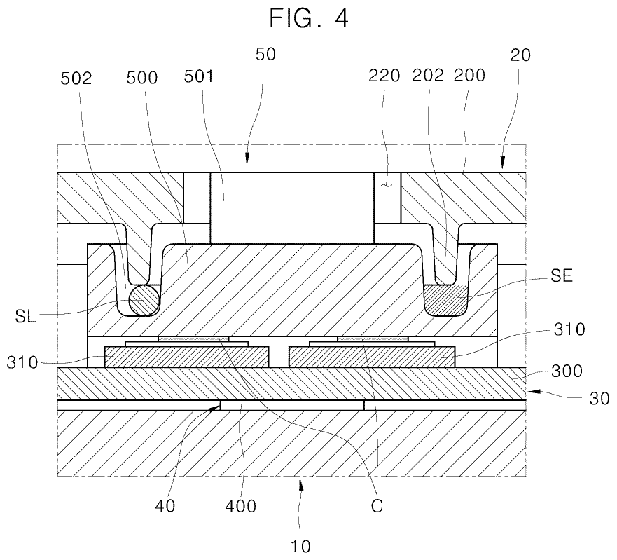

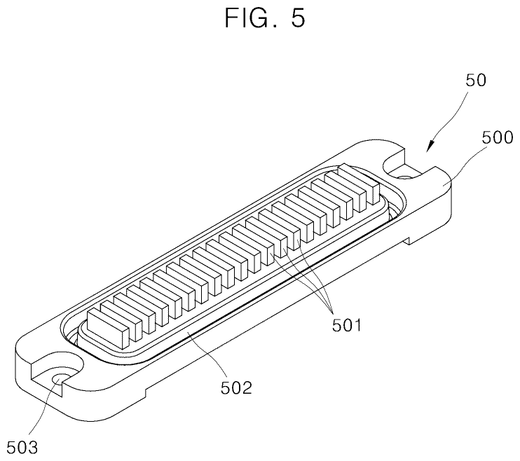

FIG. 4 is a cross-sectional view of a first embodiment of a cover heat sink portion of the electronic device according to the present disclosure. FIG. 5 is a perspective view of the first embodiment of the cover heat sink portion of the electronic device according to the present disclosure.

The motor housing portion 10, the cover portion 20, the cover body 200, the cover body protrusion 202, the cover hole portion 220, the circuit board portion 30, the circuit board body 300, the electronic element portion 310, the housing heat sink portion 40, the housing heat sink body 400, the cover heat sink portion 50, the cover heat sink body 500, the cover heat sink fin 501, and the cover heat sink groove 502 shown in FIGS. 4 and 5 are identical to the motor housing portion 10, the cover portion 20, the cover body 200, the cover body protrusion 202, the cover hole portion 220, the circuit board portion 30, the circuit board body 300, the electronic element portion 310, the housing heat sink portion 40, the housing heat sink body 400, the cover heat sink portion 50, the cover heat sink body 500, the cover heat sink fin 501, and the cover heat sink groove 502 shown in FIGS. 1 to 3. Therefore, the description of the identical configuration may be omitted.

Referring to FIGS. 4 and 5, it may be seen that the cover heat sink portion 50 is configured to be positioned between the cover portion 20 and the circuit board portion 30. The cover heat sink body 500 may be positioned to make contact with the cover body 200 and the electronic element portion 310.

The cover body protrusion 202 may be inserted into the cover heat sink groove 502 formed in the cover heat sink body 500. A sealing (SL) and/or sealant (SE) may be positioned in the cover heat sink groove 502.

The sealing (SL) may include an elastic material, which may be deformed by an external force and generate an elastic force. According to an embodiment, the sealing (SL) may include rubber. The sealing (SL) may be positioned in the cover heat sink groove 502 and make contact with the cover body protrusion 202. Accordingly, the sealing (SL) may seal the space between the cover heat sink body 500 and the cover body protrusion 202, so that one side and the other side of the cover hole portion 220 may be blocked.

The sealant (SE) may include an adhesive material. According to an embodiment, the sealant (SE) may include grease. The sealant (SE) may be positioned in the cover heat sink groove 502 so that one side and the other side of the cover hole portion 220 may be blocked.

As one side and the other side of the cover hole portion 220 are thus blocked by the sealing (SL) and/or sealant (SE), foreign substances may be prevented from entering the interior of the electronic device 1.

A heat transfer member C may be positioned on the cover heat sink body 500. According to an embodiment, the heat transfer member C may be positioned on the surface where the cover heat sink body 500 makes contact with the electronic element portion 310. The heat transfer member C may make contact with the electronic element portion 310 and the cover heat sink body 500 to transfer the heat generated from the electronic element portion 310 to the cover heat sink body 500. Accordingly, the heat dissipation performance of the cover heat sink portion 50 for the electronic element portion 310 may be improved. The heat transfer member C may be provided with thermal grease.

FIG. 6 is a cross-sectional view of a second embodiment of the cover heat sink portion of the electronic device according to the present disclosure. FIG. 7 is a perspective view of the second embodiment of the cover heat sink portion of the electronic device according to the present disclosure.

The motor housing portion 10, the cover portion 20, the cover body 200, the cover hole portion 220, the circuit board portion 30, the circuit board body 300, the electronic element portion 310, the housing heat sink portion 40, the housing heat sink body 400, the cover heat sink portion 50, the cover heat sink body 500, and the cover heat sink fin 501 shown in FIGS. 6 and 7 are identical to the motor housing portion 10, the cover portion 20, the cover body 200, the cover hole portion 220, the circuit board portion 30, the circuit board body 300, the electronic element portion 310, the housing heat sink portion 40, the housing heat sink body 400, the cover heat sink portion 50, the cover heat sink body 500, and the cover heat sink fin 501 shown in FIGS. 1 to 3. Therefore, the description of the identical configuration may be omitted.

The cover heat sink portion 50 may include the cover heat sink plate 504. The cover heat sink plate 504 may extend to protrude from the cover heat sink body 500. The cover heat sink plate 504 may extend from the cover heat sink body 500 and be inserted into the cover body 200. As the cover heat sink plate 504 is inserted into the cover body 200, the cover heat sink body 500 may be secured to the cover body 200.

The cover portion 20 may be made by insert molding. Through a process of positioning the cover heat sink portion 50 in a mold for forming the cover portion 20 and injecting the raw material for the cover portion 20, the cover heat sink plate 504 may be insert-molded while being inserted into the cover portion 20.

As the cover portion 20 and the motor housing portion 10 are coupled in a state where the cover heat sink portion 50 is secured to the cover portion 20, the cover heat sink body 500 may make contact with the electronic element portion 310 and apply pressure to the electronic element portion 310. Accordingly, the cover heat sink body 500 and the electronic element portion 310 may be positioned to be in close contact.

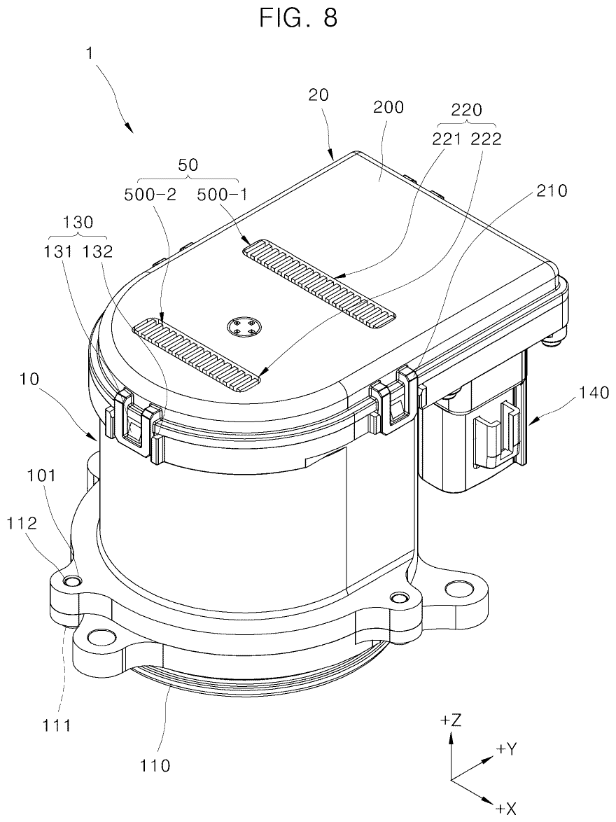

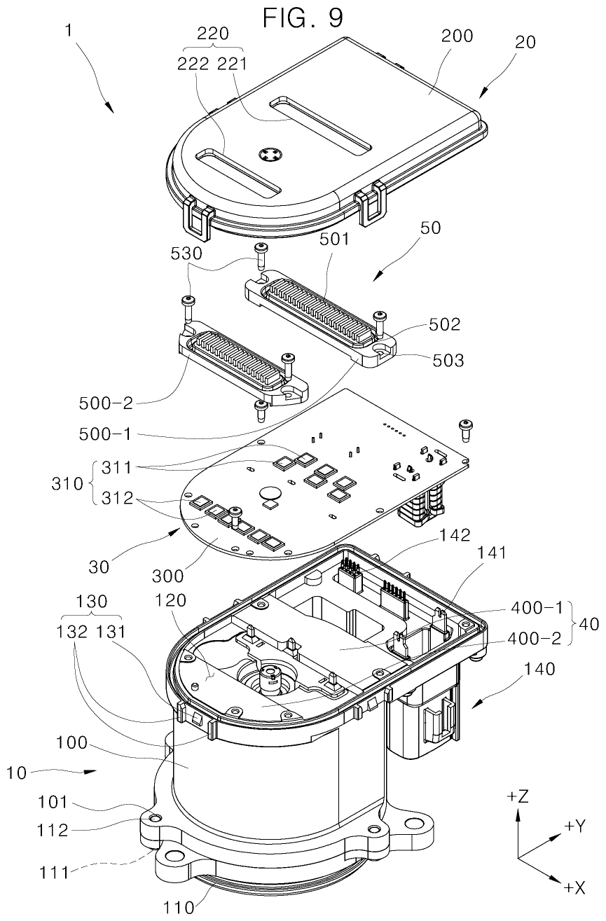

FIG. 8 is a perspective view of an electronic device according to another embodiment of the present disclosure. FIG. 9 is an exploded perspective view of the electronic device according to another embodiment of the present disclosure.

The motor housing portion 10, the cover portion 20, the circuit board portion 30, the housing heat sink portion 40, and the cover heat sink portion 50 shown in FIGS. 8 and 9 are identical to the motor housing portion 10, the cover portion 20, the circuit board portion 30, the housing heat sink portion 40, and the cover heat sink portion 50 shown in FIGS. 1 to 3. Therefore, the description of the identical configuration may be omitted.

In FIGS. 8 and 9, a plurality of cover hole portions 220, a plurality of electronic element portions 310, a plurality of housing heat sink portions 40, and a plurality of cover heat sink portions 50 may be provided.

According to an embodiment, the cover hole portion 220 may include a first cover hole 221 and a second cover hole 222. The electronic element portion 310 may include a first electronic element portion 311 and a second electronic element portion 312. The housing heat sink portion 40 may include a first housing heat sink body 400-1 and a second housing heat sink body 400-2. The cover heat sink portion 50 may include a first cover heat sink body 500-1 and a second cover heat sink body 500-2.

The first electronic element portion 311 and the second electronic element portion 312 may perform the same function.

According to an embodiment, the first electronic element portion 311 may perform a function and the second electronic element portion 312 may not perform a function in a general situation. Based on a situation where the first electronic element portion 311 is non-operational, the second electronic element portion 312 may perform the function of the first electronic element portion 311. The second electronic element portion 312 may be configured to have a redundancy structure for the first electronic element portion 311.

According to another embodiment, the first electronic element portion 311 and the second electronic element portion 312 may perform functions simultaneously. The second electronic element portion 312 may perform a function that assists the first electronic element portion 311.

The first electronic element portion 311 and the second electronic element portion 312 may be positioned on the circuit board body 300. The first electronic element portion 311 may make contact with the first cover heat sink body 500-1 of the cover heat sink portion 50 and the second electronic element portion 312 may make contact with the second cover heat sink body 500-2 of the cover heat sink portion 50. Accordingly, the heat of the first electronic element portion 311 and the heat of the second electronic element portion 312 may be dissipated by the first cover heat sink body 500-1 and the second cover heat sink body 500-2, respectively.

The first cover heat sink body 500-1 and the second cover heat sink body 500-2 may be positioned in the first cover hole 221 and the second cover hole 222 of the cover hole portion 220, respectively.

According to an embodiment, the first cover heat sink body 500-1 and the second cover heat sink body 500-2 may be secured to the motor housing portion 10 in the manner shown in FIGS. 4 and 5. According to another embodiment, the first cover heat sink body 500-1 and the second cover heat sink body 500-2 may be secured to the cover portion 20 in the manner shown in FIGS. 6 and 7.

The heat of the first electronic element portion 311 may be dissipated by the first housing heat sink body 400-1 of the housing heat sink portion 40 positioned in a location corresponding to where the first electronic element portion 311 is positioned. The heat of the second electronic element portion 312 may be dissipated by the second housing heat sink body 400-2 of the housing heat sink portion 40 positioned in a location corresponding to where the second electronic element portion 312 is positioned.

Through the above configuration, the electronic device 1 may improve the heat dissipation performance while maintaining volume thereof and improve durability. Furthermore, the electronic device 1 may operate through the redundancy structure of the electronic element portion 310 even in a failed state.

Although embodiments of the present disclosure have been described with reference to the accompanying drawings, these embodiments are for illustrative purposes only, and those skilled in the art will appreciate that various modifications and other equivalent embodiments can be made from these embodiments disclosed herein. In addition, the present disclosure may also be used in other fields. Thus, the true technical scope of the present disclosure should be defined by the following claims.

What is claimed is:

1. An electronic device, comprising:
a motor housing portion wherein a motor is positioned;
a cover portion coupled with the motor housing portion and configured to include a cover hole portion;
a circuit board portion configured to include an electronic element portion that controls the motor and generates heat and positioned between the motor housing portion and the cover portion;
a housing heat sink portion positioned between the circuit board portion and the motor housing portion and in contact with one side of the circuit board portion to dissipate heat; and
a cover heat sink portion positioned to be inserted into the cover hole portion between the circuit board portion and the cover portion and in contact with an opposite side of the circuit board portion to dissipate heat.

2. The electronic device as claimed in claim 1, wherein
the cover heat sink portion includes:
a cover heat sink body configured to make contact with the electronic element portion; and
a cover heat sink fin protruding from the cover heat sink body.

3. The electronic device as claimed in claim 2, wherein the cover heat sink portion further includes a cover heat sink groove recessed in the cover heat sink body to surround the cover heat sink fin, and
the cover portion includes a cover body and a cover body protrusion protruding from the cover body and inserted into the cover heat sink groove to block the cover hole portion.

4. The electronic device as claimed in claim 2, wherein the cover heat sink portion is secured to the motor housing portion and applies pressure to the circuit board portion in a direction of the motor housing portion.

5. The electronic device as claimed in claim 3, wherein the cover heat sink portion includes a cover heat sink hole provided with a through-hole in the cover heat sink body and a cover heat sink coupling member passing through the cover heat sink hole and coupled with the motor housing portion.

6. The electronic device as claimed in claim 2, wherein the cover heat sink portion is insert-molded with the cover portion, secured to the cover portion, and applies pressure to the circuit board portion in a direction of the motor housing portion.

7. The electronic device as claimed in claim 1, wherein the cover heat sink portion makes contact with the electronic element portion positioned on the opposite side of the circuit board portion, and the housing heat sink portion is positioned to correspond to a position of the electronic element portion on one side of the circuit board portion.

8. The electronic device as claimed in claim 7, wherein the electronic element portion comprises a first electronic element portion and a second electronic element portion.

9. The electronic device as claimed in claim 8, wherein the cover heat sink portion includes a first cover heat sink body configured to make contact with the first electronic element portion and a second cover heat sink body configured to make contact with the second electronic element portion.

10. The electronic device as claimed in claim 8, wherein the housing heat sink portion includes a first housing heat sink body positioned to correspond to a position of the first electronic element portion and a second housing heat sink body positioned to correspond to a position of the second electronic element portion.
